(19) United States
(12) Patent Application Publication
(10) Pub. No.: US 2024/0203774 A1
(43) Pub. Date: Jun. 20, 2024

(54) APPARATUS FOR TRANSFERRING SUBSTRATE

(71) Applicant: SEMES CO., LTD., Chungcheongnam-do (KR)

(72) Inventors: Kyo Bong KIM, Seongnam-si (KR); Ki Won HAN, Anseong-si (KR); Sang-Oh KIM, Seoul (KR); Hee Jae BYUN, Yongin-si (KR); Hee Chan KIM, Hwaseong-si (KR); Sang Hyeop LEE, Hwaseong-si (KR)

(21) Appl. No.: 18/536,845

(22) Filed: Dec. 12, 2023

(30) Foreign Application Priority Data
Dec. 15, 2022 (KR) 10-2022-0175924

(51) Int. Cl. H01L 21/677; B25J 11/00; B25J 15/00; H01L 21/687

(52) U.S. Cl. CPC H01L 21/67742; B25J 11/0095; B25J 15/0014; H01L 21/68707

(57) ABSTRACT

The inventive concept provides a substrate transfer apparatus. The substrate transfer apparatus includes a base; a first transfer arm configured to have a first arm link connected to the base and a first end effector connected to the first arm link, and which operates between a contract position and an expand position; and a guide member aligning a substrate placed on the first end effector while the first transfer arm backwardly moves from the expand position to the contract position.

### CROSS-REFERENCE TO RELATED APPLICATIONS

A claim for priority under 35 U.S.C. § 119 is made to Korean Patent Application No. 10-2022-0175924 filed on Dec. 15, 2022, in the Korean Intellectual Property Office, the entire contents of which are hereby incorporated by reference.

### BACKGROUND

Embodiments of the inventive concept described herein relate to a substrate transfer apparatus.

In general, a semiconductor element manufacturing process is performed by repeatedly performing various unit processes such as an exposing process, an etching process, a diffusion process, a deposition process, and a metal process on a substrate or a wafer (hereinafter referred to as a substrate). The substrates are put into a facility of each unit process while loaded on a carrier. A substrate loaded on the carrier within the facility is taken in and taken out by a substrate transfer apparatus.

A conventional substrate transfer apparatus is equipped with a hand supporting the substrate at a front end of the arm. The substrate is transferred while supported by the hand. If the substrate is misplaced on the hand with some distortion, the substrate crashes during the transferring or a significant adverse effect on the process occurs.

### SUMMARY

Embodiments of the inventive concept provide a substrate transfer apparatus for transferring a substrate after always aligning the substrate in a certain position.

Embodiments of the inventive concept provide a substrate transfer apparatus at which a substrate alignment is possible without a separate driving system.

The technical objectives of the inventive concept are not limited to the above-mentioned ones, and the other unmentioned technical objects will become apparent to those skilled in the art from the following description.

The inventive concept provides a substrate transfer apparatus. The substrate transfer apparatus includes a base; a first transfer arm configured to have a first arm link connected to the base and a first end effector connected to the first arm link, and which operates between a contract position and an expand position; and a guide member aligning a substrate placed on the first end effector while the first transfer arm backwardly moves from the expand position to the contract position.

In an embodiment, the guide member includes a first guide and a second guide for guiding both sides of the substrate; and while the first transfer arm backwardly moves, the first guide moves and the second guide does not move.

In an embodiment, the first guide moves together with the first arm link.

In an embodiment, the first arm link includes: a first arm which is rotatable in a horizontal direction on the base; and a second arm which is rotatable in a horizontal direction on a front end of the first arm, and wherein the first guide is installed on the second arm.

In an embodiment, the first guide includes: a fixing bracket installed on a side of the second arm; and a touch block provided at the fixing bracket and which contacts a side of the substrate.

In an embodiment, a surface of the touch block in contact with the side of the substrate is curved.

In an embodiment, the second guide is fixedly installed on the base.

In an embodiment, the first guide and the second guide each further include: a touch block contacting the side of the substrate; and a plunger for moving the touch block from a no-touch position to a touch position to contact the touch block to the side of the substrate when the first transfer arm is in the contract position.

In an embodiment, the substrate transfer apparatus further includes: a second transfer arm configured to have a second arm link connected to the base and a second end effector connected to the second arm link and which operates between the contract position and the expand position, and wherein the first end effector and the second end effector overlap each other when the first transfer arm and the second transfer arm are each in the contract position, and the second guide is provided at the second arm link.

In an embodiment, when the second transfer arm backwardly moves from the expand position to the contract position, the second guide moves and the first guide does not move.

The inventive concept provides a substrate transfer apparatus. The substrate transfer apparatus includes a base; a left transfer arm configured to have a first arm link connected to the base and a first end effector on which a substrate is placed and which operates between a contract position and an expand position; a right transfer arm configured to have a second arm link connected to the base and a second end effector on which the substrate is placed and which operates between the contract position and the expand position; and a guide member for aligning the substrate when the left transfer arm or the right transfer arm backwardly moves from the expand position to the contact position.

In an embodiment, the guide member includes a first guide and a second guide for guiding both sides of the substrate; and wherein the first guide is provided on the left transfer arm, and the second guide is provided on the right transfer arm.

In an embodiment, when the left transfer arm backwardly moves, the first guide moves to align the substrate while the second guide does not move.

In an embodiment, when the right transfer arm backwardly moves, the second guide moves to align the substrate while the first guide does not move.

In an embodiment, the first guide moves together with the first arm link, and the second guide moves together with the second arm link.

In an embodiment, the first arm link includes: a left first arm which is rotatable in a horizontal direction on the base; and a left second arm which is rotatable in a horizontal direction on a front end of the left first arm, and wherein the second arm link includes: a right first arm which is rotatable in a horizontal direction on the base; and a right second arm which is rotatable in a horizontal direction on the front end of the right first arm, and wherein the first guide is installed on the left second arm, and the second guide is installed on the right second arm.

In an embodiment, the first guide and the second guide includes: a fixing bracket; and a touch block provided at the fixing bracket and contacting a side of the substrate.

In an embodiment, the first guide and the second guide further include a plunger for moving the touch block from a no-touch position to a touch position to contact the touch block to the side of the substrate, when the left transfer arm and the right transfer arm are in the contract position.

The inventive concept provides a substrate transfer apparatus. The substrate transfer apparatus includes a base; a left transfer arm having a first arm link connected to the base, a first guide installed on the first arm link, and a first end effector connected to the first arm link, and configured to operate between a contract position and an expand position; and a right transfer arm having a second arm link connected to the base, a second guide installed on the second arm link, and second end effector connected to the second arm link, and configured to operate between the contract position and the expand position; and wherein the first end effector and the second end effector overlap each other when the left transfer arm and the right transfer arm are each in the contract position, when the left transfer arm backwardly moves, the first guide moves to align the substrate placed on the first end effector, while the second guide does not move, and when the right transfer arm backwardly moves, the second guide moves to align the substrate placed on the second end effector, while the first guide does not move.

In an embodiment, the first arm link includes: a left first arm which is rotatable in a horizontal direction on the base; a left second arm which is rotatable in a horizontal direction on a front end of the left first arm, and the second arm link includes: a right first arm which is rotatable in the horizontal direction on the base; a right second arm which is rotatable in the horizontal direction on the front end of the right first arm, and wherein the first guide is installed on the left second arm, and the second guide is installed on the right second arm.

According to an embodiment of the inventive concept, a substrate may be transferred after the substrate is always aligned to a certain position.

According to an embodiment of the inventive concept, a weight lightening and a simplification of a structure is possible due to implementing a guide to an arm.

According to an embodiment of the inventive concept, an alignment of a substrate is possible without a configuration of an actuator, a controller, a cable, etc for a substrate alignment.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a perspective view illustrating a substrate transfer apparatus according to an embodiment of the inventive concept.

FIG. 2A and FIG. 2B are plan views of the substrate transfer apparatus illustrated in FIG. 1.

FIG. 3 is a side view of the substrate transfer apparatus illustrated in FIG. 1.

FIG. 4 is a schematic configuration diagram of the substrate transfer apparatus.

FIG. 5 is a diagram for illustrating a first guide.

FIG. 6 is a diagram illustrating a stepwise backward operation of a left transfer arm.

FIG. 7 illustrates a movement trajectory of a touch block during a backward operation of a left transfer arm.

FIG. 8 is a diagram illustrating a substrate transport apparatus according to a second embodiment of the inventive concept.

FIG. 9 and FIG. 10 illustrate a modified embodiment of a guide member.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

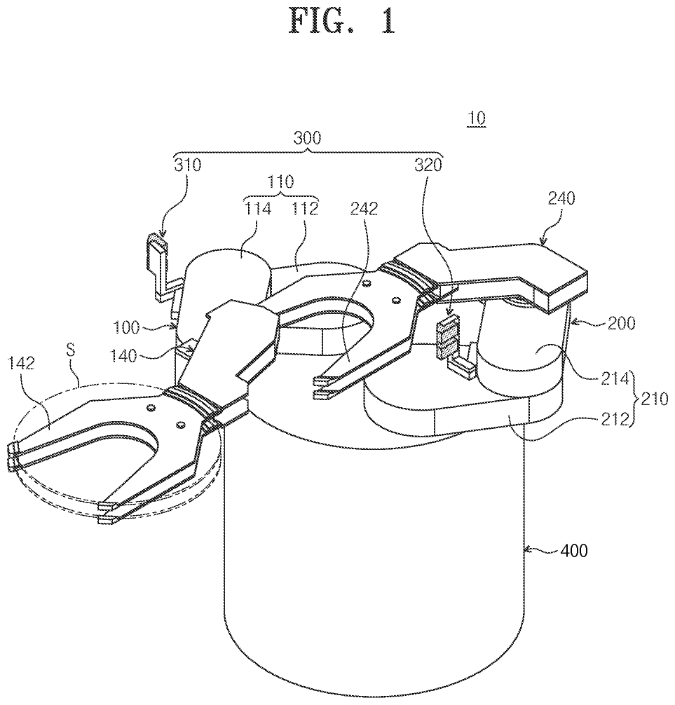

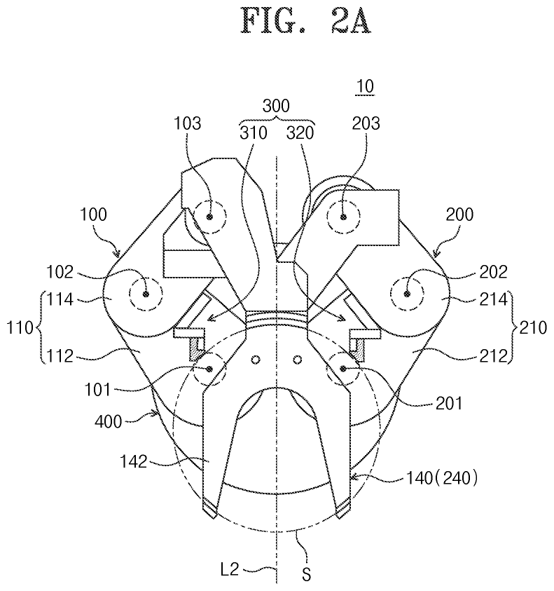

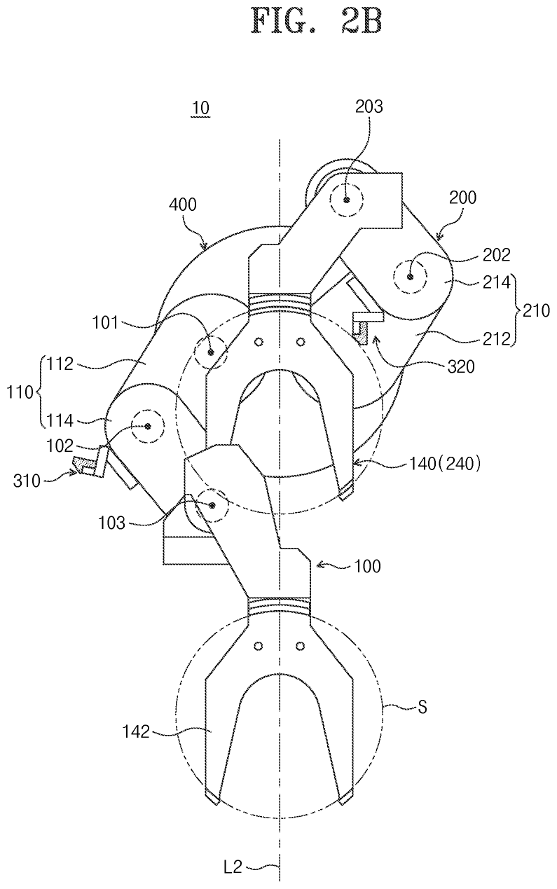

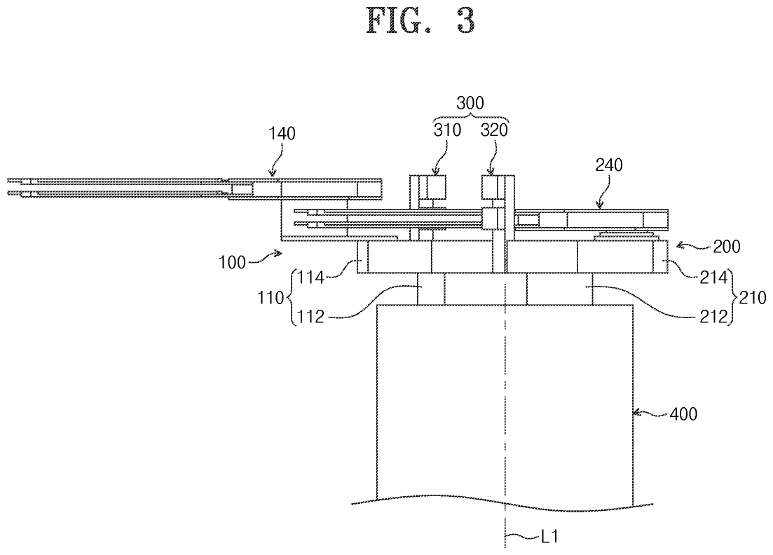

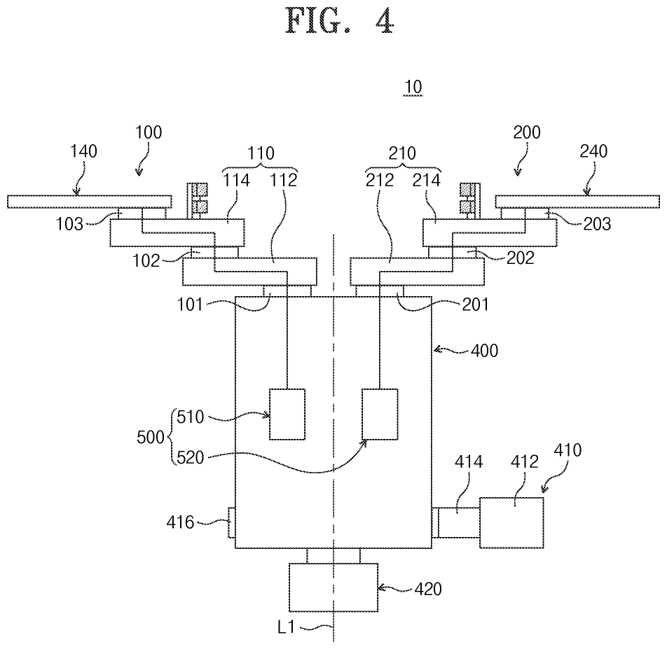

FIG. 1 is a perspective view illustrating a substrate transfer apparatus according to an embodiment of the inventive concept, FIG. 2A and FIG. 2B are plan views of the substrate transfer apparatus illustrated in FIG. 1, and FIG. 3 is a side view of the substrate transfer apparatus illustrated in FIG. 1. Also, FIG. 4 is a schematic configuration diagram of the substrate transfer apparatus.

Referring to FIG. 1 to FIG. 4, the substrate transfer apparatus 10 is also called a SCARA (Selective Compliance Automatic Robot Arm) robot. The substrate transfer apparatus 10 includes a left transfer arm 100 and a right transfer arm 200 which perform straight and rotational movements simultaneously or individually on a plane, that is, joint movements. The left transfer arm 100 and the right transfer arm 200 may be connected to a base 400. When viewed from a plane, the left transfer arm 100 and the right transfer arm 200 can be arranged symmetrically with respect to a centerline L1 passing through a center of the base 400.

The base 400 may be rotated around a first vertical axis L1 and may be linearly moved up and down. The substrate transfer apparatus 10 may include a rotation driver 410 which rotates the base 400 and a vertical mover 420 which linearly moves the base 400 in a vertical direction. In an embodiment, the rotation driver 410 may include a motor 412, a pulley 414, and a belt 416, and the vertical mover 420 may be provided in an assembly structure having a cylinder. The detailed configuration and operation thereof are known techniques and will be omitted.

The left transfer arm 100 includes a first arm link 110 connected to the base 400 and a first end effector 140 connected to the first arm link 110. The first arm link 110 may include a left first arm 112 and a left second arm 114 connected to each other by a joint.

An edge of the left first arm 112 may be connected to the base 400, and the other edge of the left first arm 112 may be connected to the left second arm 114. The left first arm 112 may be disposed on the base 400. The left first arm 112 may be connected to a bottom rotation shaft 101 connected to the base 400. The left first arm 112 may be rotated on the base 400 with respect to the bottom rotation shaft 101.

The left second arm 114 may be disposed on the left first arm 112. An edge of the left second arm 114 may be connected to the left first arm 112, and the other edge of the left second arm 114 may be connected to the first end effector 140. The left second arm 114 may be connected to a top rotation shaft 102 connected to the left first arm 112. The left second arm 114 may be rotated on the left first arm 112 with respect to the top rotation shaft 102. As described above, the first arm link may have, for example, a SCARA (Selective Compliance Automatic Robot Arm) arrangement.

The first end effector 140 may be disposed on the left second arm 114. The first end effector 140 may include a paddle 142 on which a substrate S for transfer is positioned. An edge of the first end effector 140 may be connected to an end rotation shaft 103 connected to the left second arm 114. The first end effector 140 may be rotated on the left second arm 114 with respect to the end rotation shaft 103.

The right transfer arm 200 includes a second arm link 210 connected to the base 400 and a second end effector 240 connected to the second arm link 210. The second arm link 210 includes a right first arm 212 and a right second arm 214 connected to each other by a joint.

An edge of the right first arm 212 may be connected to the base 400, and the other edge of the right first arm 212 may be connected to the right second arm 214. The right first arm 212 may be disposed on the base 400. The right first arm 212 may be connected to the bottom rotation shaft 201 connected to the base 400. The right first arm 212 may be rotated on the base 400 with respect to the bottom rotation shaft 201.

The right second arm 214 may be disposed on the right first arm 212. An edge of the right second arm 214 may be connected to the right first arm 212, and the other edge of the right second arm 214 may be connected to the second end effector 240. The right second arm 214 may be connected to a top rotation shaft 202 connected to the right first arm 212. The right second arm 214 may be rotated on the right first arm 212 with respect to the top rotation shaft 202.

The second end effector 240 may be disposed on the right second arm 214. The second end effector 240 may include a paddle 242 on which the substrate S for transfer is positioned. An edge of the second end effector 240 may be connected to the end rotation shaft 203 connected to the right second arm 214. The second end effector 240 may be rotated on the right second arm 214 with respect to the end rotation shaft 203.

As described above, the second arm link 210 has a SCARA (Selective Compliance Automatic Robot Arm) arrangement.

The first end effector 140 and the second end effector 240 may include, but are not limited to, a paddle shape. In addition, the end effectors 140 and 240 of the left transfer arm 100 and the right transfer arm 200 move within different horizontal planes to enable an unrestricted movement of the first arm link 110 and the second arm link 210. That is, the first end effector 140 and the second end effector 240 are positioned at different heights.

In an embodiment of the inventive concept, two paddles 142 and 242 are illustrated for example in the first and second end effector 140 and 240, and in other embodiments, the end effector 140 and 240 may have any number of paddles. In addition, the substrate S may be representative, and may be any size and shape such as 200 mm, 300 mm, 450 mm, or larger semiconductor wafers, reticles for flat screen displays, pellicles, or panels.

The driving unit 500 may include a first driver 510 and a second driver 520. The first driver 510 may provide a driving force to the left transfer arm 100. The second driver 520 may provide a driving force to the right transfer arm 200. The first driver 510 may be provided in the base 400 and the first arm link 110, and the second driver 520 may be provided in the base 400 and the second arm link 210.

In general, in a Selective Compliance Automatic Robot Arm apparatus, the first driver 510 and the second driver 520 rotate the arm link 110 and 210 and the end effector 140 and 240 through a conventional power transmission configuration including a motor, a belt, and a pulley configuration. That is, the left transfer arm 100 and the right transfer arm 200 expand or contract by each driver, and the substrate S may be transferred parallel to a linear path L2 which matches a rotation center axis L1 of the base 400. Since the first driver 510 and the second driver 520 are known technologies, detailed configuration and operation descriptions will be omitted.

In the aforementioned structure, the left transfer arm 100 and the right transfer arm 200 are described as being driven independently by each driver, but the inventive concept is not limited to this, and the left transfer arm 100 and the right transfer arm 200 may be driven in conjunction with one driver.

The left transfer arm 100 and the right transfer arm 200 transfer the substrate between an expand position and a contract position. FIG. 2A shows a state in which both the left transfer arm 100 and the right transfer arm 200 are in the contract position A1, and FIG. 2B shows a state in which the left transfer arm 100 is in the expand position A2. The first end effector 140 and the second end effector 240 are provided to overlap each other when the left transfer arm 100 and the right transfer arm 200 are in contract positions, respectively. In addition, when the left transfer arm 100 is expanded, the first end effector 140 and the right transfer arm 200 are expanded, and the second end effector 240 may be in the same position when viewed from a plane.

The guide member 300 aligns the substrate during the backward operation of the left transfer arm 100 and the right transfer arm 200. The backward operation is an operation that moves from the expand position to the contract position. The guide member 300 may include a first guide 310 and a second guide 320. The first guide 310 may be provided to the left transfer arm 100, and the second guide 320 may be provided to the right transfer arm 200.

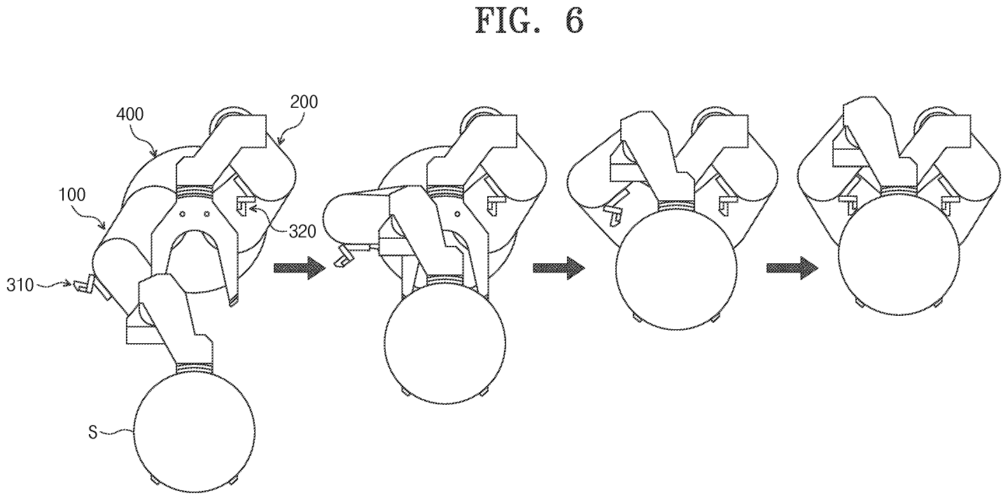

In an embodiment, the first guide 310 may be installed on the left second arm 114. FIG. 6 is a diagram illustrating a stepwise backward operation of the left transfer arm. Referring to FIG. 6, the first guide 310 moves together with the left second arm 114 during a backward operation of the left transfer arm 100. The first guide 310 may be installed at any position of the left second arm 114 to be in contact with a side surface of the substrate S placed on the end effector 140 when the left transfer arm 100 is in the contract position. Therefore, during the backward operation of the left transfer arm 100, the first guide 310 moves while the second guide 320 is stopped to align the substrate S placed on the first end effector 140.

The second guide 320 may be installed on the right second arm 214. The second guide 320 moves together with the right second arm 214 during a backward operation of the right transfer arm 200. The second guide 320 may be installed at any position of the right second arm 214 to be in contact with the side surface of the substrate S placed on the end effector 240 when the right transfer arm 200 is in the contract position. Therefore, during a backward operation of the right transfer arm 200, the second guide 320 moves while the first guide 310 is stopped to align the substrate S placed on the second end effector 240.

The first guide 310 and the second guide 320 may be arranged symmetrically with respect to the center line L1 passing through the center of the base 400 when viewed from a plane. The first guide 310 and the second guide 320 have the same configuration.

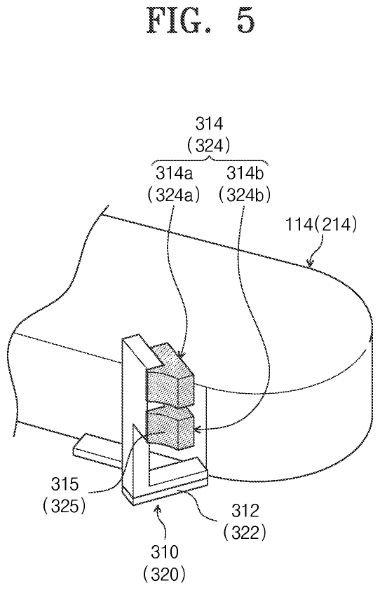

FIG. 5 is a diagram for illustrating a first guide.

Referring to FIG. 5, the first guide 310 may include a fixing bracket 312 and a touch block 314. The fixing bracket 312 may be installed on a side surface of the left second arm 114. The touch block 314 is provided on the fixing bracket 312. The touch block 314 may be provided such that a surface 315 in contact with the side surface of the substrate S is curved. A length of the touch block 314 is sufficient to cover both the first and second end effector 140 and 240. In an embodiment, the touch block 314 of the first guide 310 may include a top part 314a in contact with the side of the substrate positioned on the first end effector 140 and a bottom part 314b in contact with the side of the substrate positioned on the second end effector 240. Like the first guide 310, the touch block 324 of the second guide 320 may include a top part 324a in contact with the side of the substrate positioned on the first end effector 140 and a bottom part 324b in contact with the side of the substrate positioned on the second end effector 20.

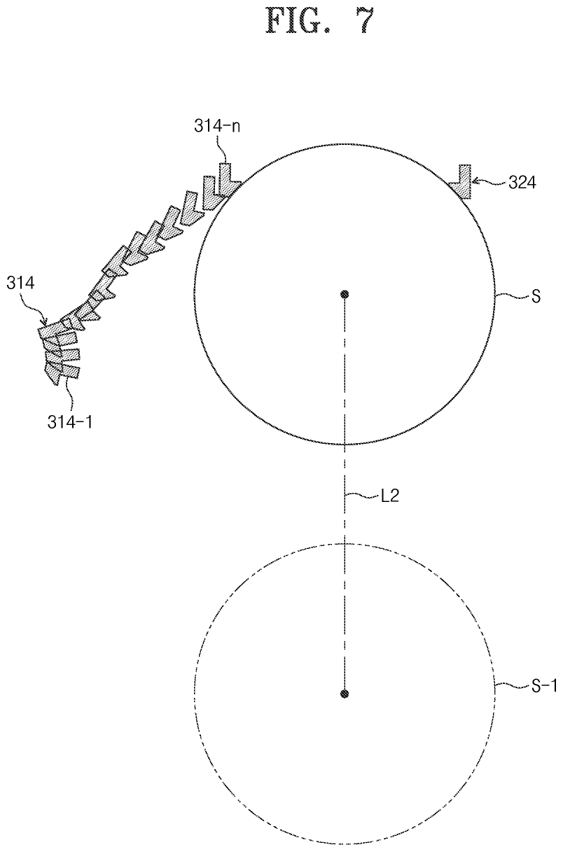

FIG. 7 illustrates a movement trajectory of a touch block during a backward operation of a left transfer arm.

The first touch block 314-1 is at a position at which the left transfer arm 100 is expanded, and the last touch block 314-n is at a position at which the left transfer arm 100 is contracted. The substrate S−1 indicated by a dotted line is at a position at which the left transfer arm 100 is expanded, and the substrate S indicated by a solid line is at a position at which the left transfer arm 100 is contracted. As described above, the first guide 310 has a movement trajectory in which an interference with the substrate does not occur during the backward (or forward) operation of the left transfer arm 100. In addition, the first guide 310 moves together with the left second arm 114 during the backward operation of the left transfer arm 100 and approaches the side of the substrate to align the substrate S. That is, the first guide 310 comes into contact with the side surface of the substrate without a separate actuator.

The second guide 320 has a movement trajectory symmetrical to the first guide 310 during the backward operation of the right transfer arm 200, and the description thereof will be omitted.

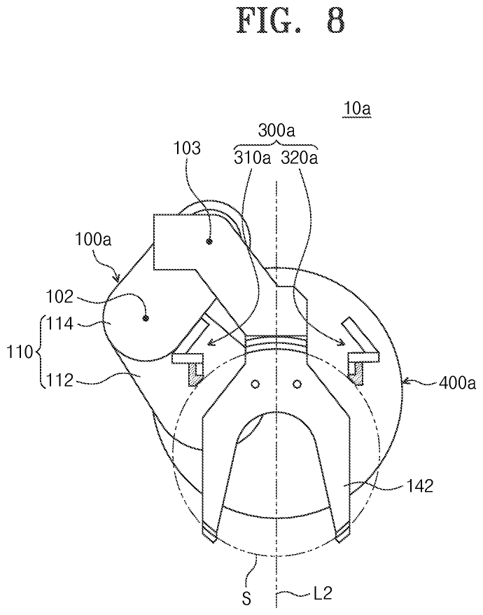

FIG. 8 is a diagram illustrating a substrate transfer apparatus according to a second embodiment of the inventive concept.

As shown in FIG. 8, the substrate transfer apparatus 10a may include a base 400a, a single transfer arm 100a which performs a joint movement, and a guide member 300a. Since the base 400a, the transfer arm 100a, and the guide member 300a are provided with a configuration and function similar to the base 400, the left transfer arm 100, and the guide member 300 described in FIG. 1, a modified example will be described below.

In this embodiment, since the substrate transfer apparatus 10a is equipped with only one transfer arm 100a, the first guide 310a of the guide member 300a is installed on the transfer arm 100a and the second guide 320a is installed on the base 400a. The first guide 310 moves together during an expanding and contracting operation of the transfer arm 100a, and the second guide 320a maintains a fixed state.

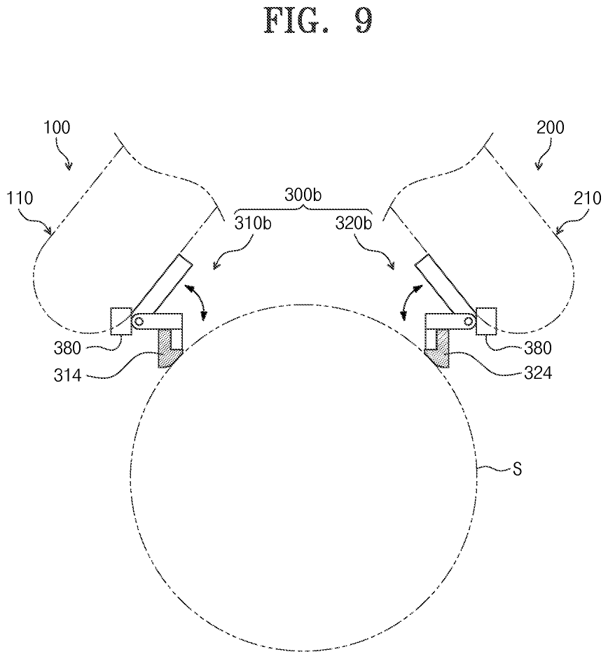

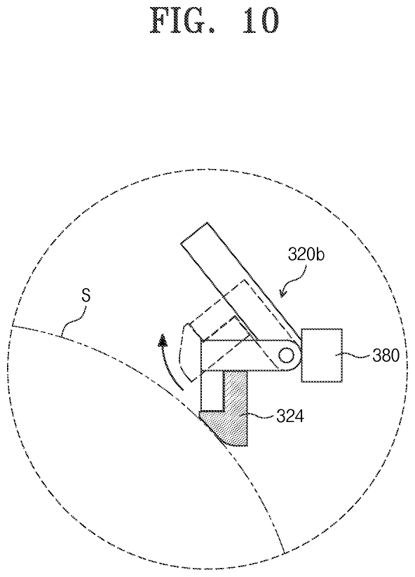

FIG. 9 and FIG. 10 illustrate a modified example of a guide member.

Referring to FIG. 9 and FIG. 10, the guide member 300b includes a first guide 310b and a second guide 320b, which are provided with a configuration and function generally similar to that of the first guide 310 and the second guide 320 illustrated in FIG. 2A, and thus a modified example will be described based on the difference from this embodiment. For convenience of drawing, some configurations of the left transfer arm 100 and the right transfer arm 200 are omitted.

As shown in FIG. 9 and FIG. 10, the first guide 310b and the second guide 320b include a plunger 380. The plunger 380 moves the touch blocks 314 and 324 from a no-touch position to a touch position (or a touch position to a no-touch position). In FIG. 10, the touch block 324 displayed as a solid line is the touch position. The touch position is a position at which the touch block 314 and 324 contacts the side of the substrate S when any one of the left transfer arm 100 or the right transfer arm 200 is contracted. In FIG. 10, the touch block 324 indicated by a dotted line is the no-touch position. The no-touch position is a position spaced apart from the side surface of the substrate S. When the left transfer arm 100 is backwardly (or forwardly) operated, the touch block 314, 324 is moved to a non-contact position, and when the left transfer arm 100 is stopped after the backward operation is completed, it can be moved to the touch position to align the substrate S. The operation of the touch blocks 314 and 324 is simultaneously performed. The touch block is shown to rotate on the fixing bracket 312, but is not limited to it, and can also be applied to a structure in which an entire first guide (second guide) rotates on the left transfer arm 100 (the right transfer arm).

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate transfer apparatus comprising:
a base;
a first transfer arm configured to have a first arm link connected to the base and a first end effector connected to the first arm link, and which operates between a contract position and an expand position; and
a guide member aligning a substrate placed on the first end effector while the first transfer arm backwardly moves from the expand position to the contract position.

2. The substrate transfer apparatus of claim 1, wherein the guide member includes a first guide and a second guide for guiding both sides of the substrate; and
while the first transfer arm backwardly moves, the first guide moves and the second guide does not move.

3. The substrate transfer apparatus of claim 2, wherein the first guide moves together with the first arm link.

4. The substrate transfer apparatus of claim 2, wherein the first arm link includes:
a first arm which is rotatable in a horizontal direction on the base; and
a second arm which is rotatable in a horizontal direction on a front end of the first arm, and
wherein the first guide is installed on the second arm.

5. The substrate transfer apparatus of claim 4, wherein the first guide includes:
a fixing bracket installed on a side of the second arm; and
a touch block provided at the fixing bracket and which contacts a side of the substrate.

6. The substrate transfer apparatus of claim 5, wherein a surface of the touch block in contact with the side of the substrate is curved.

7. The substrate transfer apparatus of claim 2, wherein the second guide is fixedly installed on the base.

8. The substrate transfer apparatus of claim 2, wherein the first guide and the second guide each further include:
a touch block contacting the side of the substrate; and
a plunger for moving the touch block from a no-touch position to a touch position to contact the touch block to the side of the substrate when the first transfer arm is in the contract position.

9. The substrate transfer apparatus of claim 2 further comprising:
a second transfer arm configured to have a second arm link connected to the base and a second end effector connected to the second arm link and which operates between the contract position and the expand position, and
wherein the first end effector and the second end effector overlap each other when the first transfer arm and the second transfer arm are each in the contract position, and
the second guide is provided at the second arm link.

10. The substrate transfer apparatus of claim 9, wherein when the second transfer arm backwardly moves from the expand position to the contract position, the second guide moves and the first guide does not move.

11. A substrate transfer apparatus comprising:
a base;
a left transfer arm configured to have a first arm link connected to the base and a first end effector on which a substrate is placed and which operates between a contract position and an expand position;
a right transfer arm configured to have a second arm link connected to the base and a second end effector on which the substrate is placed and which operates between the contract position and the expand position; and
a guide member for aligning the substrate when the left transfer arm or the right transfer arm backwardly moves from the expand position to the contact position.

12. The substrate transfer apparatus of claim 11, wherein the guide member includes a first guide and a second guide for guiding both sides of the substrate; and
wherein the first guide is provided on the left transfer arm, and
the second guide is provided on the right transfer arm.

13. The substrate transfer apparatus of claim 12, wherein when the left transfer arm backwardly moves, the first guide moves to align the substrate while the second guide does not move.

14. The substrate transfer apparatus of claim 12, wherein when the right transfer arm backwardly moves, the second guide moves to align the substrate while the first guide does not move.

15. The substrate transfer apparatus of claim 12, wherein the first guide moves together with the first arm link, and the second guide moves together with the second arm link.

16. The substrate transfer apparatus of claim 12, wherein the first arm link includes:
a left first arm which is rotatable in a horizontal direction on the base; and
a left second arm which is rotatable in a horizontal direction on a front end of the left first arm, and
wherein the second arm link includes:
a right first arm which is rotatable in a horizontal direction on the base; and
a right second arm which is rotatable in a horizontal direction on the front end of the right first arm, and
wherein the first guide is installed on the left second arm, and
the second guide is installed on the right second arm.

17. The substrate transfer apparatus of claim 12, wherein the first guide and the second guide includes:
a fixing bracket; and
a touch block provided at the fixing bracket and contacting a side of the substrate.

18. The substrate transfer apparatus of claim 17, wherein the first guide and the second guide further include a plunger for moving the touch block from a no-touch position to a touch position to contact the touch block to the side of the substrate, when the left transfer arm and the right transfer arm are in the contract position.

19. A substrate transfer apparatus comprising:
a base;
a left transfer arm having a first arm link connected to the base, a first guide installed on the first arm link, and a first end effector connected to the first arm link, and configured to operate between a contract position and an expand position; and
a right transfer arm having a second arm link connected to the base, a second guide installed on the second arm link, and second end effector connected to the second arm link, and configured to operate between the contract position and the expand position; and
wherein the first end effector and the second end effector overlap each other when the left transfer arm and the right transfer arm are each in the contract position, and
when the left transfer arm backwardly moves, the first guide moves to align the substrate placed on the first end effector, while the second guide does not move, and
when the right transfer arm backwardly moves, the second guide moves to align the substrate placed on the second end effector, while the first guide does not move.

20. The substrate transfer apparatus of claim 19, wherein the first arm link includes:
a left first arm which is rotatable in a horizontal direction on the base;
a left second arm which is rotatable in a horizontal direction on a front end of the left first arm, and
the second arm link includes:
a right first arm which is rotatable in the horizontal direction on the base;
a right second arm which is rotatable in the horizontal direction on the front of the right first arm, and
wherein the first guide is installed on the left second arm, and
the second guide is installed on the right second arm.
